(19) United States
(12) Patent Application Publication
(10) Pub. No.: US 2005/0206000 A1
(43) Pub. Date: Sep. 22, 2005

(54) Barrier for copper integrated circuits

(76) Inventors: Sanjeev Aggarwal, Plano, TX (US); Kelly J. Taylor, Allen, TX (US); Srinivas Raghavan, Plano, TX (US); Stephan Grunow, Dallas, TX (US); Satyavolu S. Papa Rao, Garland, TX (US)

Correspondence Address: TEXAS INSTRUMENTS INCORPORATED, P O BOX 655474, M/S 3999, DALLAS, TX, 75265, US

(21) Appl. No.: 10/805,121

(22) Filed: Mar. 19, 2004

(51) Int. Cl. H01L 29/40; H01L 23/52; H01L 23/48; H01L 21/8242

(52) U.S. Cl. 257/758

(57) ABSTRACT

An integrated circuit copper interconnect structure is formed by forming a dielectric layer (90) over a semiconductor substrate (10). Trenches (110) and vias (120) are formed in the dielectric layer (90) and a barrier layer (130) is formed in the trenches (110) and vias (120) using material such as iridium, iridium oxide, ruthenium, ruthenium oxide, rhodium, rhodium oxide, rhenium, rhenium oxide, platinum, platinum oxide, palladium and palladium oxide. Copper (147) is then used to fill the remaining area in the trenches (110) and vias (120).

### FIELD OF THE INVENTION

The invention is generally related to the field of integrated circuits and more specifically to a novel process to form an improved barrier for copper integrated circuits.

### BACKGROUND OF THE INVENTION

The individual electronic components that comprise an integrated circuit are interconnected by metal lines formed in dielectric layers that are themselves formed above the surface of the semiconductor substrate. As the operating frequency of the integrated circuit increases, the resistance of the metal lines becomes an important limitation in the performance of the integrated circuit. Earlier integrated circuits used aluminum to form the metal interconnect lines. However the use of aluminum is now being replaced by copper in an effort to reduce the electrical resistance of the metal interconnect lines. An example of copper interconnect lines according to the prior art is shown in FIG. 1.

As shown in FIG. 1, a dielectric layer 20 is formed over a semiconductor 10. Electronic components such as transistors, capacitors, diodes, etc will be formed in the semiconductor 10 but have been omitted from FIG. 1 for clarity. As shown in the Figure, a copper line 70 is formed in the dielectric layer. The copper line 70 represents one of any number of copper lines that will be used to interconnect the electronic components. A second dielectric layer 30 can be formed above the first dielectric layer 20 and addition copper lines 72, 73 and vias 71 can be formed in the second dielectric layer 30. In general the via 71 is a structure that connects a copper line from a first metal level (i.e. 70) to a copper line from a second level (i.e., 72). In general any number of different metal levels can be used to form the integrated circuit.

Copper metal lines and vias 70, 72, 73, and 71 are formed using a damascene technique. In the damascene technique a trench is first formed in the dielectric layer. Following the formation of the trench, barrier layers 40, 50 are formed in the trench to prevent the diffusion of copper into and through the various dielectric layers. In the example shown in FIG. 1 the barrier layers 40 and 50 are tantalum nitride and tantalum respectively. Following the formation of the barrier layers 40, 50, a copper seed layer 60 is formed in the trench. The copper seed layer comprises a layer of copper formed using a deposition technique such as physical vapor deposition (PVD). Following the formation of the copper seed layer 60, copper is used to fill the remaining opening in the trench using deposition techniques such as electroplating.

As the current size of the metal interconnect lines continues to shrink, the barrier layers 40, 50 will become an increasingly larger percentage of the total metal in the interconnect. This will have the negative effect of increasing the overall resistance of the metals lines. This is due to the fact that the resistivity of barriers layers such as tantalum and/or tantalum nitride is about 200 μΩcm which is greater than a hundred times the 1.7 μΩcm resistivity of copper. As the size of the metal interconnect lines shrink, the thickness of the barrier layers has to remain above a certain minimum value to maintain the effectiveness of the barrier. The thickness of the copper however is reduced along with the reduction in the size of the metal lines leading to a larger contribution of the resistance of the barrier layers 40, 50 to the overall resistance of the interconnect.

There is therefore a need for an improved metal interconnect structure. The instant invention addresses this need.

### SUMMARY OF THE INVENTION

The instant invention describes an integrated circuit copper interconnect structure. In an embodiment of the invention, a dielectric layer is formed over a semiconductor substrate. Trenches and vias are formed in the dielectric layer and a barrier layer is formed in the trenches and vias using material such as iridium, iridium oxide, ruthenium, ruthenium oxide, rhodium, rhodium oxide, rhenium, rhenium oxide, platinum, platinum oxide, palladium and palladium oxide. Copper is then used to fill the remaining area in the trenches and vias. In a further embodiment of the instant invention, a copper seed layer is formed beneath the copper and over the barrier layer.

### BRIEF DESCRIPTION OF THE DRAWINGS

In the drawings:

FIG. 1 is a cross-sectional diagram showing copper metal lines according to the prior art.

FIGS. 2(a) to FIG. 2(c) are cross-sectional diagrams showing an embodiment of the instant invention.

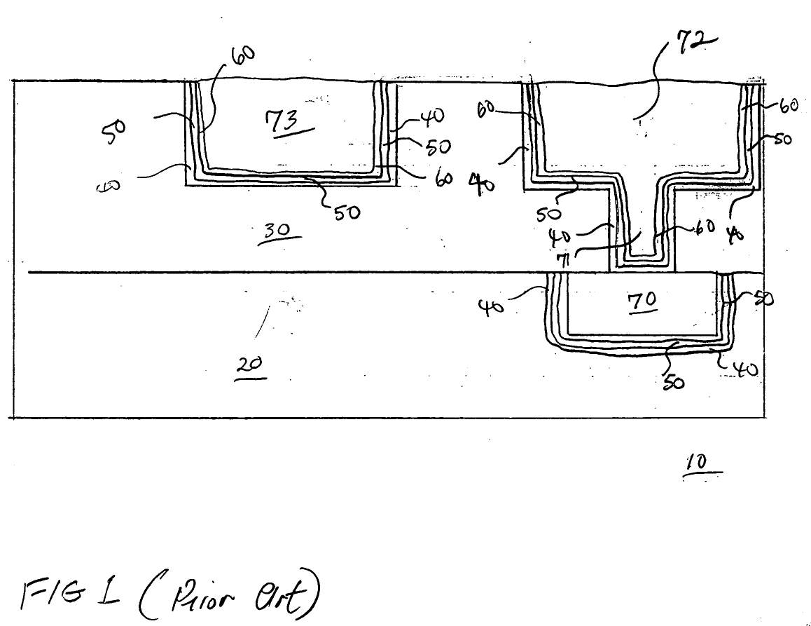

Common reference numerals are used throughout the Figures to represent like or similar features. The Figures are not drawn to scale and are merely provided for illustrative purposes.

### DETAILED DESCRIPTION OF THE INVENTION

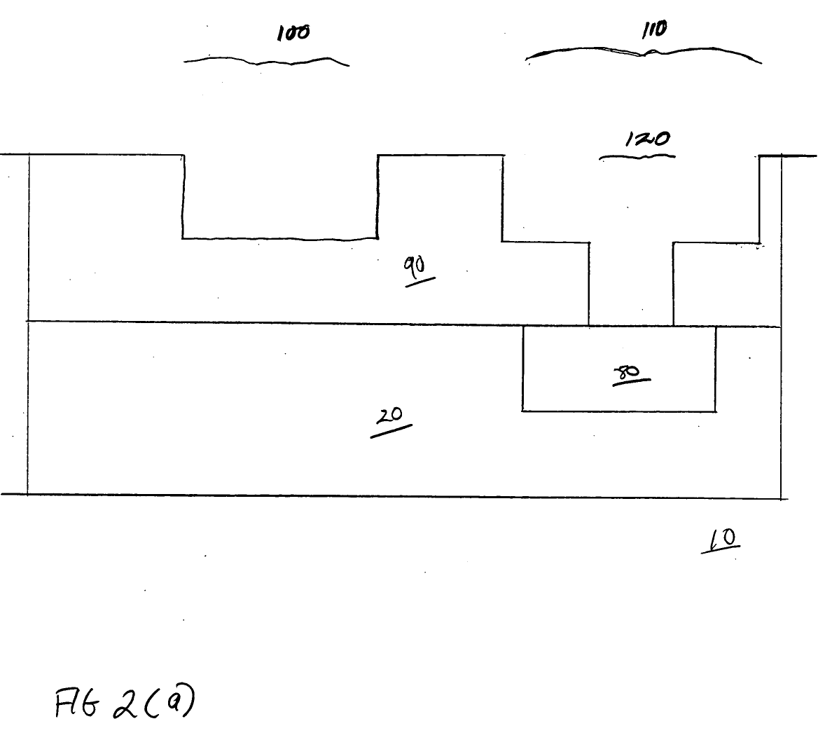

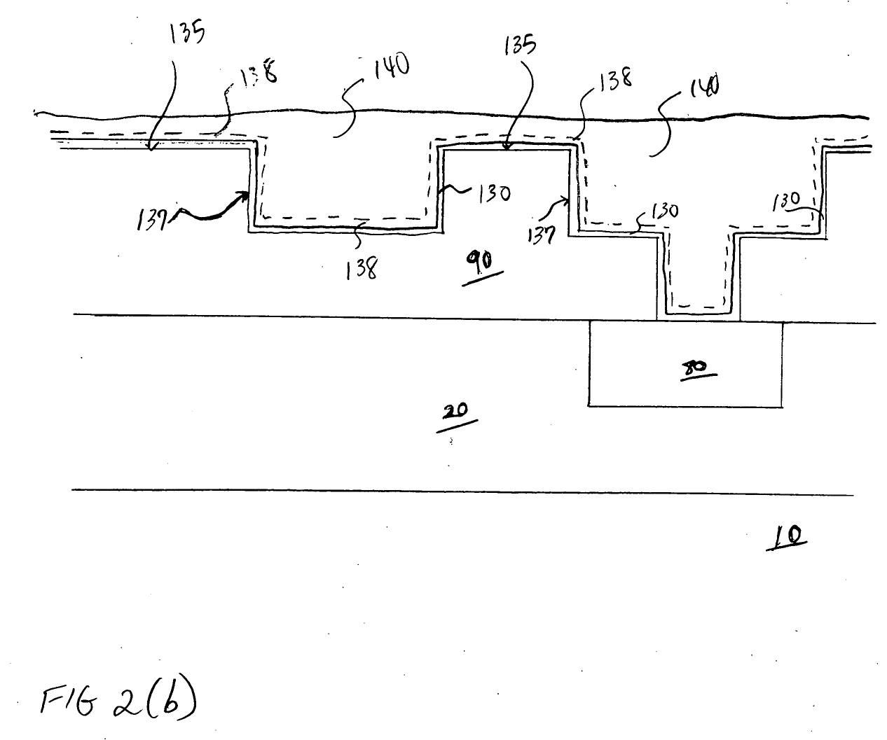

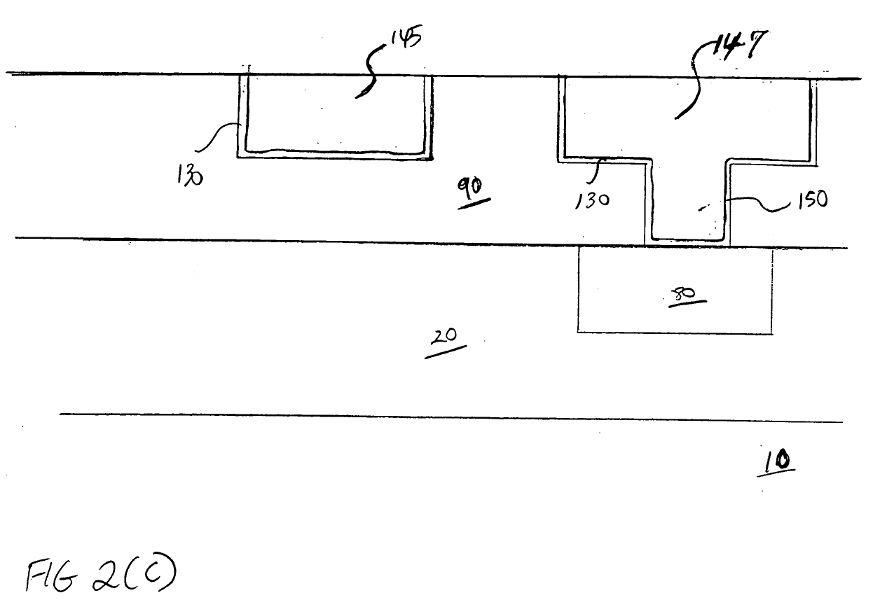

While the following description of the instant invention revolves around FIGS. 2(a) to FIG. 2(c), the instant invention can be utilized in any semiconductor device structure. The methodology of the instant invention provides a solution to reducing the size of the metal interconnect structures while significantly decreasing the overall resistivity of the lines.

The following description of the instant invention will be related to FIGS. 2(a) to FIG. 2(c). As shown in FIG. 2(a), a dielectric layer 20 is formed over a semiconductor substrate 10. The semiconductor substrate comprises electronic devices such as transistors, capacitors, diodes, etc which are not shown in the Figures for clarity. Any number of intervening layers can be formed above the semiconductor 10 and below the dielectric layer 20. The dielectric layer 20 can be formed using any suitable dielectric material. In various embodiments of the instant invention the dielectric layer 20 can comprise silicon oxide, siloxane spin-on glass (SOG), silsesquioxanes, xerogels, fluorinated silicon glass (FSG), organosilicate glass (OSG), and any other suitable dielectric material. A metal interconnect line 80 is formed in the dielectric layer 20 using known processing techniques. In an embodiment of the instant invention the metal interconnect line 80 comprises copper.

A second dielectric layer 90 is formed over the first dielectric layer 80. The second dielectric layer 90 can comprise silicon oxide, siloxane spin-on glass (SOG), silsesquioxanes, xerogels, fluorinated silicon glass (FSG), organosilicate glass (OSG), and any other suitable dielectric material. Following the formation of the second dielectric layer 90, various trenches 100, 110 and vias 120 are formed in the second dielectric layer 90 using methods such as the single damascene process or the dual damascene process. The trenches 110, 110 and vias 120 are formed using both standard photolithographic patterning and dielectric etching methods. Metal interconnect lines will be formed in the trenches 110, 110, and the via 120 will connect the metal line formed in trench 110 with the metal line 80 that was formed in the underlying dielectric layer.

Following the formation of the trenches 100, 110 and vias 120, a first layer 130 is formed in the trenches 100, 110 and vias 120 as shown in FIG. 2(b). In various embodiments of the instant invention the first layer 130 can comprise iridium (Ir), ruthenium (Ru), rhodium (Rh), rhenium (Re), platinum (Pt), palladium (pd) and any combination of the above metals. The above group of metals will be referred to as group A. In addition, oxides of the above metals such as iridium oxide, ruthenium oxide, palladium oxide, rhodium oxide, rhenium oxide, and platinum oxide can be used to form the first layer 130. The above group of oxides will be referred to as group B. In a further embodiment of the instant invention, the first layer 130 comprises iridium (Ir) either singly or in combination with other suitable elements. A further embodiment comprises iridium as part of a multi-layered film stack to form the barrier/wetting/seed layer and/or voltage-drop-reduction stack for subsequent copper integration. The first layer 130 can also comprise a plurality of layers of different materials such a layers comprising iridium (Ir), ruthenium (Ru), rhodium (Rh), rhenium (Re), platinum (Pt), palladium (pd) and layers comprising iridium oxide, ruthenium oxide, palladium oxide, rhodium oxide, rhenium oxide, and platinum oxide. Therefore in an embodiment, the first layer 130 could be comprised of at least one layer comprised of a material from group A and at least one layer comprised of a material from Group B. Multiple layers formed from materials from each group can also be used to form the first layer 130.

In the embodiment where the first layer 130 in FIG. 2(b) comprises iridium, the iridium layer 130 can be formed at thicknesses from about 50 Å to 250 Å using physical vapor deposition (PVD), chemical vapor deposition (CVD), and/or atomic layer deposition (ALD). In any of the above described deposition processes, the temperature during the process can vary from below room temperature to 450° C. In the case where PVD is used to form the iridium layer 130, the PVD layer can be formed using an Ar sputter process or a self-ionized metal sputter process, as known to people skilled in the art. In addition a combination of PVD deposition followed by a etch process or a simultaneous PVD deposition and etch process can be used to form the iridium layer 130. During the PVD processes, the DC power during deposition can be tuned to achieve deposition rates of 2 Å/s to 50 Å/s. The deposition AC bias power in an ionized PVD system can be tuned for appropriate side wall coverage and can be 0 W to 1000 W. Similarly the RF power and AC power to an RF coil can be tuned for good step coverage from 0 W to 2000 W. The sidewall coverage and field thickness of iridium layer 130 can be optimized to reduce series resistance effects seen during plating. The goal would be to have reasonable sidewall coverage with very high field coverage. The sidewall is represented by the vertical surfaces (e.g. 137 in FIG. 2(b)) and the field by the horizontal surfaces (e.g. 135 in FIG. 2(b)). For example, to lower the resulting resistance of the structure, the ratio of the deposited thicknesses of the iridium layer 130 on the sidewall versus the field could be 1:5 for sidewall:field. The CVD of iridium and/or ruthenium for the formation of the first layer 130 can be performed using the precursors Bis(Ethylcyclopentadienyl),(2,4-Dimethylpentadienyl) and/or (Ethylcyclopentadienyl). A combination of the chemical vapor deposition (CVD) and PVD iridium depositions may be used, with the PVD iridium designed to reduce the voltage drop produced across the wafer during copper electroplating while not significantly affecting the barrier thickness on the sidewall of the trenches and vias.

In the case where iridium is used to form the layer 130, the iridium can be polycrystalline or amorphous in structure or composed of an amorphous layer superposed with a crystalline layer. The amorphousness can be ascertained and/or identified via a transmission electron microscope (TEM). The TEM can be employed to detect/identify presence of crystalline features within the layer. Failure of detecting/identifying presence of substantial crystalline features, also referred to as crystallinity, via the TEM defines the layer as being amorphous. It is appreciated that other suitable mechanisms can be employed to determine whether or not the layer is amorphous. However, it is also appreciated that some mechanisms in certain instances (e.g., x-ray diffraction) can fail to properly define the layer as being amorphous. Additionally, it is appreciated that the layer can have a percentage of crystalline features (e.g., degrees of amorphousness) and still be sufficiently amorphous in accordance with the present invention.

Following the formation of the first layer 130, copper 140 is used to fill the trenches and vias. In the instant invention no copper seed layer is formed on the first layer 130 prior to the filling of the trenches and vias with copper. In an embodiment of the instant invention the copper 140 is formed using an electroplating technique. For the case where iridium is used to form the first layer 130, the semiconductor wafer comprising the iridium layer 130 is first cleaned in a 30% hydrogen peroxide solution for about 3 minutes. The wafer is then rinsed and dried. It is immediately inserted into a “plating bath” solution containing copper sulfate, sulfuric acid and water. Chemical additives can be added to the bath to improve the quality of the resulting copper 140. Voltage is applied between the iridium semiconductor wafer as the cathode and an anode copper source to electrochemically deposit copper on the iridium surface. Alternatively, copper can be deposited on the iridium surface by electroless deposition or an initial layer by electroless deposition followed by copper electroplating. While the instant invention does not entail the need for a copper seed layer between the barrier layer 130 and the copper 140, it should be noted that the use of a copper seed layer 138, e.g., deposited using PVD or CVD is optional. Such an optional seed layer 138 is shown in FIG. 2(b) for completeness.

Following the formation of the copper structure 140, chemical mechanical polishing can be used to remove the excess copper resulting in the copper interconnect lines 145, 147 and the copper via 150 shown in FIG. 2(c). The copper via structure 150 electrically connects the copper line 147 with the underlying copper line 80. It should be noted that the optional copper seed layer 138 has been omitted from FIG. 2(c) for clarity.

The instant invention offers numerous advantages over the existing prior art. The metals described above are immiscible to copper and provide an excellent barrier to copper. In addition, iridium can act as a seed layer for electroplating therefore eliminating the need for the formation of a separate (optional) copper seed layer. Finally, iridium strongly adheres to the underlying dielectric layer.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

1. A copper interconnect structure, comprising:
a semiconductor substrate;
a dielectric layer over said semiconductor substrate;
a trench in said dielectric layer;
a barrier layer in said trench wherein said barrier layer comprises a material from the group consisting of iridium (Ir), ruthenium (Ru), rhodium (Rh), rhenium (Re), platinum (Pt), and palladium (pd); and
copper filling said trench over said barrier layer.

2. The copper interconnect structure of claim 1 further comprising;
a via in said dielectric layer;
a trench in said dielectric layer;
a barrier layer in said via wherein said barrier layer comprises a material from the group consisting of iridium (Ir), ruthenium (Ru), rhodium (Rh), rhenium (Re), platinum (Pt), and palladium (pd); and
copper filling said via over said barrier layer.

3. The copper interconnect structure of claim 2 wherein said via is positioned beneath said trench.

4. A copper interconnect structure, comprising:
a semiconductor substrate;
a dielectric layer over said semiconductor substrate;
a trench in said dielectric layer;
a first barrier layer in said trench wherein said barrier layer comprises a material from the group consisting of iridium oxide, ruthenium oxide, rhodium oxide, rhenium oxide, platinum oxide, and palladium oxide; and
copper filling said trench over said barrier layer.

5. The copper interconnect structure of claim 4 further comprising;
a via in said dielectric layer;
a trench in said dielectric layer;
a first barrier layer in said via wherein said first barrier layer comprises a material from the group consisting of iridium oxide, ruthenium oxide, rhodium oxide, rhenium oxide, platinum oxide, and palladium oxide; and
copper filling said via over said barrier layer.

6. The copper interconnect structure of claim 5 wherein said via is positioned beneath said trench.

7. The copper interconnect of claim 6 further comprising a second barrier layer wherein said second barrier layer comprises a material selected from the group consisting of iridium (Ir), ruthenium (Ru), rhodium (Rh), rhenium (Re), platinum (Pt), and palladium (pd).

8. A method for forming a copper interconnect structure, comprising:
forming a dielectric layer over a semiconductor substrate;
forming a trench in said dielectric layer;
forming a via in said trench;
deposition a first barrier layer in said trench and via wherein said first barrier layer comprises a material selected from the group consisting of iridium (Ir), ruthenium (Ru), rhodium (Rh), rhenium (Re), platinum (Pt), and palladium (pd); and
filling said trench and said via with copper formed over said first barrier layer.

9. The method of claim 8 further comprising forming a second barrier layer beneath said copper wherein said second barrier layer comprises a material selected from the group consisting of iridium oxide, ruthenium oxide, rhodium oxide, rhenium oxide, platinum oxide, and palladium oxide.

10. A method for forming an integrated circuit with copper interconnects, comprising:
forming a dielectric layer over a semiconductor substrate;
forming a trench in said dielectric layer;
forming a via in said trench;
deposition a first barrier layer in said trench and via wherein said first barrier layer comprises a material selected from the group consisting of iridium oxide, ruthenium oxide, rhodium oxide, rhenium oxide, platinum oxide, and palladium oxide; and
filling said trench and said via with copper formed over said first barrier layer.
